(19) United States
(12) Patent Application Publication
(10) Pub. No.: US 2023/0227966 A1
(43) Pub. Date: Jul. 20, 2023

(54) Methods Of Forming Ruthenium-Containing Films Without A Co-Reactant

(71) Applicant: MERCK PATENT GMBH, Darmstadt (DE)

(72) Inventors: Guo LIU, Haverhill, MA (US); Jacob WOODRUFF, Lexington, MA (US); Ravindra KANJOLIA, North Andover, MA (US)

(21) Appl. No.: 18/011,737

(22) PCT Filed: Jun. 28, 2021
(86) PCT No.: PCT/EP2021/067605

§ 371 Date: Dec. 20, 2022

Related U.S. Application Data
(60) Provisional application No. 63/046,911, filed on Jul. 1, 2020.

(51) Int. Cl. C23C 16/18; C23C 16/455

(52) U.S. Cl. CPC C23C 16/18; C23C 16/45523

(57) ABSTRACT

Methods of forming ruthenium-containing films by pulsed chemical vapor deposition are provided. The methods include at least one deposition cycle. The deposition cycle includes pulsing a zerovalent Ru precursor with a carrier gas in the absence of a co-reactant onto a surface of a substrate, and delivering a purge gas to the surface of the substrate.

### FIELD

The present invention relates to methods of forming ruthenium-containing films without using a co-reactant, such as pulsed chemical vapor deposition methods.

### BACKGROUND

Various precursors are used to form thin films and a variety of deposition techniques have been employed. Such techniques include reactive sputtering, ion-assisted deposition, chemical vapor deposition (CVD) (also known as metalorganic CVD or MOCVD), and atomic layer deposition (also known as atomic layer epitaxy). CVD and ALD processes are increasingly used as they have the advantages of enhanced compositional control, high film uniformity, and effective control of doping. Moreover, CVD and ALD processes provide excellent conformal step coverage on highly nonplanar geometries associated with modem microelectronic devices.

CVD is a chemical process whereby precursors are used to form a thin film on a substrate surface. In a typical CVD process, the precursors are passed over the surface of a substrate (e.g., a wafer) in a low pressure or ambient pressure reaction chamber. The precursors react and/or decompose on the substrate surface creating a thin film of deposited material. Plasma can be used to assist in reaction of a precursor or for improvement of material properties. Volatile by-products are removed by gas flow through the reaction chamber. The deposited film thickness can be difficult to control because it depends on coordination of many parameters such as temperature, pressure, gas flow volumes and uniformity, chemical depletion effects, and time.

ALD is a chemical method for the deposition of thin films. It is a self-limiting, sequential, unique film growth technique based on surface reactions that can provide precise thickness control and deposit conformal thin films of materials provided by precursors onto surface substrates of varying compositions. In ALD, the precursors are separated during the reaction. The first precursor is passed over the substrate surface producing a monolayer on the substrate surface. Any excess unreacted precursor is pumped out of the reaction chamber. A second precursor or co-reactant is then passed over the substrate surface and reacts with the first precursor, forming a second monolayer of film over the first-formed monolayer of film on the substrate surface. Plasma may be used to assist with reaction of a precursor or co-reactant or for improvement in materials quality. This cycle is repeated to create a film of desired thickness.

Thin films, and in particular thin metal-containing films, have a variety of important applications, such as in nanotechnology and the fabrication of semiconductor devices. Examples of such applications include capacitor electrodes, gate electrodes, adhesive diffusion barriers, and integrated circuits.

The continual decrease in the size of microelectronic components has increased the need for improved thin film technologies. Further, there is a need for deposition of ruthenium (Ru) as next generation metal electrodes, caps or liners in logic and memory semiconductor manufacturing. Most existing ruthenium vapor deposition processes use oxygen-containing co-reactants, such as water, to obtain lower resistivity metal films deposited at reasonable growth rates. However, oxygen co-reactants can undesirably react with underlying films, such as metals and liners, and increase their resistivity. While methods of depositing ruthenium can use oxygen-free co-reactants, such as hydrogen, hydrazine, or ammonia, these methods can result in high resistivity ruthenium films due to incorporation of carbon and other impurities, such as nitrogen, from the co-reactant. Thus, further annealing of the ruthenium film at a high temperature in an inert gas or a reducing atmosphere, such as H₂, or an oxidizing atmosphere to remove the impurities (e.g., carbon, nitrogen, etc.) can be necessary in order to lower resistivity of the ruthenium film. However, removal of impurities by annealing can also cause significant film shrinkage. Additionally, conventional thermal CVD through rapid pyrolysis without a co-reactant can produce higher purity ruthenium films using Ru₃(CO)₁₂ or (cyclohexadiene)tricarbonylruthenium, but such processes and precursors are generally not very suitable for high aspect ratio structures. Therefore, a co-reactant free process for forming ruthenium-containing films is needed.

### SUMMARY OF THE INVENTION

Thus, provided herein are pulsed chemical vapor deposition (CVD) methods for depositing a ruthenium-containing film on a substrate. The pulsed CVD method includes at least one deposition cycle. The deposition cycle includes pulsing a zerovalent Ru precursor with a carrier gas in the absence of a co-reactant onto a surface of a substrate and delivering a purge gas to the surface of the substrate.

Other embodiments, including particular aspects of the embodiments summarized above, will be evident from the detailed description that follows.

### BRIEF DESCRIPTION OF THE DRAWINGS

FIG. 1 is a graphical representation of Ru film growth rate (nm/cycle) vs. deposition temperature (°C) for Ru films grown on a SiO₂ substrate according to Example 1.

FIG. 2A is a graphical representation of Ru film growth rate (nm/cycle) vs. H₂O pulse time (sec.) for Ru films grown on three substrates, Al₂O₃, SiO₂, and WCN, according to Example 2.

FIG. 2B is a graphical representation of Ru film resistivity (µΩ-cm) vs. H₂O pulse time (sec.) for Ru films (as-deposited Ru) grown on three substrates, Al₂O₃, SiO2, and WCN, according to Example 2.

FIG. 2C is a graphical representation of Ru film resistivity (µΩ-cm) vs. H₂O pulse time (sec.) for annealed Ru films (400° C.-annealed Ru) grown on three substrates, Al₂O₃, SiO₂, and WCN, according to Example 2.

FIG. 3A is a graphical representation of Ru film growth rate (nm/cycle) vs. reactor chamber wall/shower head and precursor delivery line temperature (°C) for Ru films grown on three substrates, Al₂O₃, SiO₂, and WCN, according to Example 3.

FIG. 3B is a graphical representation of Ru film resistivity (µΩ-cm) vs. reactor chamber wall/shower head and precursor delivery line temperature (°C) for Ru films grown on three substrates, Al₂O₃, SiO₂, and WCN, according to Example 3.

FIG. 4 is a graphical representation of Ru film growth rate (nm/cycle) vs. total purge time (sec.) for Ru films grown on three substrates, Al₂O₃, SiO₂, and WCN, according to Example 5.

FIG. 5A is a graphical representation of Ru film resistivity (µΩ-cm) vs. total purge time (sec.) for as-deposited Ru films (as-dep) and annealed Ru films (400° C. Ar-annealed) grown on an Al₂O₃ substrate according to Example 6.

FIG. 5B is a graphical representation of Ru film resistivity (µΩ-cm) vs. total purge time (sec.) for as-deposited Ru films (as-dep) and annealed Ru films (400° C. Ar-annealed) grown on a SiO₂ substrate according to Example 6.

FIG. 5C is a graphical representation of Ru film resistivity (µΩ-cm) vs. total purge time (sec.) for as-deposited Ru films (as-dep) and annealed Ru films (400° C. Ar-annealed) grown on a WCN substrate according to Example 6.

FIG. 6A is a graphical representation of Ru film growth rate (nm/cycle) vs. Ru pulse time (sec.) for Ru films grown on three substrates, Al₂O₃, SiO₂, and WCN, according to Example 7.

FIG. 6B is a graphical representation of Ru film growth rate (nm/cycle) vs. Ru pulse time (sec.) for as-deposited Ru films (as-dep) and annealed Ru films (400° C. Ar-annealed) grown on a SiO₂ substrate according to Example 7.

FIG. 6C is a graphical representation of Ru film growth rate (nm/cycle) vs. Ru pulse time (sec.) for as-deposited Ru films (as-dep) and annealed Ru films (400° C. Ar-annealed) grown on a WCN substrate according to Example 7.

FIG. 7A is a graphical representation of Ru film growth rate (nm/cycle) vs. deposition temperature (°C) for Ru films grown on three substrates, Al₂O₃, SiO2, and WCN, according to Example 8.

FIG. 7B is a graphical representation of Ru film growth rate (nm/cycle) vs. deposition temperature (°C) for as-deposited Ru films (as-dep) and annealed Ru films (400° C. Ar-annealed) grown on a SiO₂ substrate according to Example 8.

FIG. 8A is a graphical representation of Ru film resistivity (µΩ-cm) vs. deposition temperature (°C) for as-deposited Ru films (as-dep) and annealed Ru films (400° C. Ar-annealed) grown on an Al₂O₃ substrate according to Example 9.

FIG. 8B is a graphical representation of Ru film resistivity (µΩ-cm) vs. deposition temperature (°C) for as-deposited Ru films (as-dep) and annealed Ru films (400° C. Ar-annealed) grown on a SiO₂ substrate according to Example 9.

FIG. 8C is a graphical representation of Ru film resistivity (µΩ-cm) vs. deposition temperature (°C) for as-deposited Ru films (as-dep) and annealed Ru films (400° C. Ar-annealed) grown on a WCN substrate according to Example 9.

FIG. 9A is a graphical representation of Ru film thickness (nm) vs. number of cycles for Ru films grown with and without the use of an NH₃ co-reactant on an Al₂O₃ substrate according to Example 10.

FIG. 9B is a graphical representation of Ru film thickness (nm) vs. number of cycles for Ru films grown with and without the use of an NH₃ co-reactant on a SiO₂ substrate according to Example 10.

FIG. 9C is a graphical representation of Ru film thickness (nm) vs. number of cycles for Ru films grown with and without the use of an NH₃ co-reactant on a WCN substrate according to Example 10.

FIG. 10A is a graphical representation of Ru film resistivity (µΩ-cm) vs. Ru film thickness (nm) for as-deposited Ru films (as-deposited) grown with and without the use of an NH₃ co-reactant on SiO₂ and WCN substrates according to Example 11.

FIG. 10B is a graphical representation of Ru film resistivity (µΩ-cm) vs. Ru film thickness (nm) for annealed Ru films (400° C. Ar-annealed) grown with and without the use of an NH₃ co-reactant on SiO₂ and WCN substrates according to Example 11.

### DETAILED DESCRIPTION

Before describing several exemplary embodiments of the present technology, it is to be understood that the technology is not limited to the details of construction or process steps set forth in the following description. The present technology is capable of other embodiments and of being practiced or being carried out in various ways.

The inventors have discovered processes to improve ruthenium deposition and films formed therefrom. The processes may include a pulsed CVD method including at least one deposition cycle. The deposition cycle includes pulsing a zerovalent ruthenium (Ru) precursor with a carrier gas in the absence of a co-reactant onto a surface of a substrate, and delivering a purge gas to the surface of the substrate. Advantageously, the processes described herein can be performed at or below the thermal decomposition temperature of a zerovalent Ru precursor. Applicant discovered that the zerovalent Ru precursor described herein is capable of a self-catalyzed thermal dissociation during an extended purging time (i.e., time of delivery of purge gas to the substrate) at or below the thermal decomposition temperature of the precursor. Thus, this process described herein can allow for the removal of neutral ligands of the zerovalent Ru precursor and result in a ruthenium-containing film with low impurities and low resistivity.

### Definitions

For purposes of this invention and the claims hereto, the numbering scheme for the Periodic Table Groups is according to the IUPAC Periodic Table of Elements.

The term “and/or” as used in a phrase such as “A and/or B” herein is intended to include “A and B”, “A or B”, “A”, and “B”.

The terms “substituent”, “radical”, “group”, and “moiety” may be used interchangeably.

As used herein, the terms “metal-containing complex” (or more simply, “complex”) and “precursor” are used interchangeably and refer to a metal-containing molecule or compound which can be used to prepare a metal-containing film by a deposition process such as, for example, ALD or CVD. The metal-containing complex may be deposited on, adsorbed to, decomposed on, delivered to, and/or passed over a substrate or surface thereof, as to form a metal-containing film.

As used herein, the term “metal-containing film” includes not only an elemental metal film, but also a film which includes a metal along with one or more elements, for example a metal nitride film, metal silicide film, a metal carbide film and the like.

As used herein, the term “deposition process” is used to refer to any type of deposition technique, including but not limited to, CVD and ALD. In various embodiments, CVD may take the form of conventional (i.e., continuous flow) CVD, liquid injection CVD, plasma-enhanced CVD, or photo-assisted CVD. CVD may also take the form of a pulsed technique, i.e., pulsed CVD. ALD is used to form a metal-containing film by vaporizing and/or passing at least one metal complex disclosed herein over a substrate surface. For conventional ALD processes see, for example, George S. M., et al. J. Phys. Chem., 1996, 100, 13121-13131. In other embodiments, ALD may take the form of conventional (i.e., pulsed injection) ALD, liquid injection ALD, photo-assisted ALD, plasma-assisted ALD, or plasma-enhanced ALD. The term “vapor deposition process” further includes various vapor deposition techniques described in Chemical Vapour Deposition: Precursors, Processes, and Applications; Jones, A. C.; Hitchman, M. L., Eds. The Royal Society of Chemistry: Cambridge, 2009; Chapter 1, pp 1-36.

The term “alkyl” refers to a saturated hydrocarbon chain of 1 to about 8 carbon atoms in length, such as, but not limited to, methyl, ethyl, propyl and butyl. The alkyl group may be straight-chain or branched-chain. For example, as used herein, propyl encompasses both n-propyl and iso-propyl; and butyl encompasses n-butyl, sec-butyl, iso-butyl and tert-butyl. Further, as used herein, “Me” refers to methyl, and “Et” refers to ethyl.

The term “alkenyl” refers to an unsaturated hydrocarbon chain of 2 to about 6 carbon atoms in length, containing one or more double bonds. Examples include, without limitation, ethenyl, propenyl, butenyl, pentenyl and hexenyl.

The term “dienyl” refers to a hydrocarbon group containing two double bonds. A dienyl group may be linear, branched, or cyclic. Further, there are unconjugated dienyl groups which have double bonds separated by two or more single bonds; conjugated dienyl groups which have double bonds separated by one single bond; and cumulated dienyl groups which have double bonds sharing a common atom.

The term “alkoxy” (alone or in combination with another term(s)) refers to a substituent, i.e., -O-alkyl. Examples of such a substituent include methoxy (—O—CH₃), ethoxy, etc. The alkyl portion may be straight-chain or branched-chain. For example, as used herein, propoxy encompasses both n-propoxy and iso-propoxy; and butoxy encompasses n-butoxy, iso-butoxy, sec-butoxy, and tert-butoxy.

The term “cycloalkenyl” refers to a monocyclic unsaturated non-aromatic hydrocarbon having 3 to 10 carbon atoms and containing one or more double bonds. Examples include, without limitation, cyclopropenyl, cyclobutenyl, cyclopentenyl and cyclohexenyl.

### Methods of Forming Ruthenium-Containing Films

As stated above, methods of forming ruthenium-containing (Ru-containing) films are provided herein. A method may be a pulsed chemical vapor deposition (CVD) method for depositing a ruthenium-containing film. In any embodiment, the pulsed CVD method can include at least one deposition cycle. The at least one deposition cycle includes pulsing a zerovalent ruthenium (Ru) precursor, for example, with a carrier gas in the absence of a co-reactant onto a surface of a substrate and delivering a purge gas to the surface of the substrate.

In any embodiment, a zerovalent Ru precursor can be (ethylbenzyl)(1-ethyl-1,4-cyclohexadienyl)ruthenium.

In any embodiment, a zerovalent Ru precursor corresponds in structure to the following Formula I:

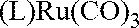

wherein: L is selected from the group consisting of a linear or branched C₂-C₆-alkenyl, a linear or branched C₁-C₆-alkyl, a C₃-C₆ cycloalkenyl, and a linear, branched, or cyclic dienyl-containing moiety; and wherein L is optionally substituted with one or more substituents independently selected from the group consisting of C₂-C₆-alkenyl, C₁-C₆-alkyl, alkoxy and NR¹R²; wherein R¹ and R² are independently alkyl or hydrogen.

In any embodiment, L may be a C₂-C₆-alkenyl group, a C₂-C₅-alkenyl group, a C₂-C₄-alkenyl group, or a C₂-C₃-alkenyl group, such as, but not limited to, ethenyl, propenyl, butenyl, pentenyl, and hexenyl.

In one embodiment, L may be a C₁-C₆-alkyl group, a C₁-C₅-alkyl group, a C₁-C₄-alkyl group, a C₁-C₃-alkyl groups, or a C₁-C₂-alkyl group, such as, but not limited to, methyl, ethyl, propyl, butyl, and pentyl.

In one embodiment, L may be a C₃-C₆-cycloalkenyl group, a C₄-C₆-cycloalkenyl group, or a C₅-C₆-cycloalkenyl group, such as, but not limited to, cyclopropenyl, cyclobutenyl, cyclopentenyl, and cyclohexenyl.

In one embodiment, L is a linear, branched, or cyclic dienyl-containing moiety. Examples of such linear, branched, or cyclic dienyl-containing moieties include butadienyl, pentadienyl, hexadienyl, cyclohexadienyl, heptadienyl and octadienyl. In a further embodiment, the linear, branched, or cyclic dienyl-containing moiety is a 1,3-dienyl-containing moiety.

In another embodiment, L is substituted with one or more substituents such as C₂-C₆-alkenyl, C₁-C₆-alkyl, alkoxy and NR¹R², where R¹ and R² are as defined above. For example, R¹ and R² may be a C₁-C₆-alkyl group, a C₁-C₅-alkyl group, a C₁-C₄-alkyl group, a C₁-C₃-alkyl group, or a C₁-C₂-alkyl group, such as, but not limited to, methyl, ethyl, propyl, butyl, pentyl, or any combination thereof. In a particular embodiment, L is a dienyl-containing moiety and substituted with one or more substituents such as C₂-C₆-alkenyl, C₁-C₆-alkyl, alkoxy and NR¹R², where R¹ and R² are as defined above, for example, a C₁-C₆-alkyl group, a C₁-C₅-alkyl group, a C₁-C₄-alkyl group, a C₁-C₃-alkyl group, or a C₁-C₂-alkyl group, such as, but not limited to, methyl, ethyl, propyl, butyl, pentyl, or any combination thereof.

Additionally or alternatively, L may be substituted with one or more C₁-C₆-alkyl groups, C₁-C₅-alkyl groups, C₁-C₄-alkyl groups, C₁-C₃-alkyl groups, or C₁-C₂-alkyl groups, such as, but not limited to, methyl, ethyl, propyl, butyl, pentyl, or any combination thereof.

Additionally or alternatively, L may be substituted with one or more C₂-C₆-alkenyl groups, C₂-C₅-alkenyl groups, C₂-C₄-alkenyl groups, or C₂-C₃-alkenyl groups, such as, but not limited to, ethenyl, propenyl, butenyl, pentenyl, hexenyl, or any combination thereof.

Additionally or alternatively, L may be substituted with one or more C₁-C₆-alkoxy groups, C₁-C₅-alkoxy groups, C₁-C₄-alkoxy groups, C₁-C₃-alkoxy groups, or C₁-C₂-alkoxy groups, such as, but not limited to, methoxy, ethoxy, propoxy, butoxy, or any combination thereof.

Examples of a zerovalent Ru precursor corresponding in structure to Formula (I) include, without limitation:
(η⁴-buta-1,3-diene)tricarbonylruthenium, also known as (BD)Ru(CO)₃;
(η⁴-2,3-dimethylbuta-1,3-diene)tricarbonylruthenium, also known as (DMBD)Ru(CO)₃;
(cyclohexadiene)tricarbonylruthenium, also known as (CHD)Ru(CO₃), and (η⁴-2-methylbuta-1,3-diene)tricarbonylruthenium.

In any embodiment, the zerovalent Ru precursor can be delivered or pulsed in the presence of a carrier gas and in the absence of a co-reactant to a surface of a substrate. Thus, the zerovalent Ru precursor can be delivered or pulsed in the absence of a co-reactant, such as, but not limited to the following co-reactants: nitrogen plasma, ammonia plasma, oxygen, air, water, H₂O₂, ozone, NH₃, H₂, i-PrOH, t-BuOH, N₂O, ammonia, an alkylhydrazine, a hydrazine, ozone, and a combination thereof. Examples of suitable carrier gases include, but are not limited to, Ar, N₂, He, CO, and combinations thereof.

The zerovalent Ru precursor, the carrier gas, or both may be pre-heated before pulsing in the deposition cycle. For example, the zerovalent Ru precursor may be pre-heated before pulsing to a temperature of about 15° C. to about 75° C., about 20° C. to about 50° C., or about 30° C. to about 40° C. The carrier gas may be pre-heated to the same or different temperature as the zerovalent Ru precursor before pulsing. For example, the carrier gas may be pre-heated before pulsing to a temperature of about 15° C. to about 110° C., about 20° C. to about 100° C., or about 40° C. to about 80° C.

In any embodiment, the zerovalent Ru precursor in a flow of the carrier gas may be delivered or pulsed for a time duration of greater than or equal to about 1 second, greater than or equal to about 2 seconds, greater than or equal to about 5 seconds, greater than or equal to about 6 seconds, greater than or equal to about 10 seconds, greater than or equal to about 15 seconds, greater than or equal to about 20 seconds, greater than or equal to about 25 seconds, or about 30 seconds; or from about 1 second to about 30 seconds, about 1 second to about 20 seconds, about 1 second to about 10 seconds, or about 5 seconds to about 10 seconds. In some embodiments, the carrier gas may be flowed before and/or after pulsing of the zerovalent Ru precursor. For example, the carrier gas may be delivered to the substrate, for example, for about 5-30 seconds, after the zerovalent Ru precursor is pulsed. It is also contemplated herein that the zerovalent Ru precursor can be evaporated and pulsed or delivered to the substrate, for example, via vapor draw delivery, without flowing the carrier gas while the zerovalent Ru precursor is delivered. The number of pulses of zerovalent Ru precursor is determined by a desired thickness of the Ru-containing film, for example, the pulses can range from 1 to 500 pulses, 1 to 300 pulses, 1 to 200 pulses, 1 to 100 pulses, 1 to 50 pulses, or 1 to 25 pulses.

The reaction conditions will be selected based on the properties of the zerovalent Ru precursor. Pulsing of the zerovalent Ru precursor can be carried out at atmospheric pressure but is more commonly carried out at a reduced pressure. For example, pulsing the zerovalent Ru precursor can be performed at pressure of greater than or equal to about 0.01 Torr, greater than or equal to about 0.1 Torr, greater than or equal to about 0.5 Torr, greater than or equal to about 1 Torr, greater than or equal to about 2 Torr, greater than or equal to about 4 Torr, greater than or equal to about 6 Torr, greater than or equal to about 8 Torr, or about 10 Torr; or from about 0.01 Torr to about 10 Torr, about 0.1 Torr to about 8 Torr, about 0.1 Torr to about 5 Torr, or about 1 Torr to about 2 Torr.

Thus, the precursors disclosed herein utilized in these methods may be liquid, solid, or gaseous. Typically, the zerovalent Ru precursors are liquids or solids at ambient temperatures with a vapor pressure sufficient to allow for consistent transport of the vapor to the process chamber.

Plasma may be used to enhance reaction of a zerovalent Ru precursor or improve film quality.

Following pulsing of the zerovalent Ru precursor, extended purging can advantageously allow for self-catalyzed thermal dissociation of the zerovalent Ru precursor at or below the thermal decomposition temperature of the precursor. Thus, in any embodiment, the purge gas may be delivered for greater than or equal to about 20 seconds, greater than or equal to about 25 seconds, greater than or equal to about 30 seconds, greater than or equal to about 45 seconds, greater than or equal to about 60 seconds, greater than or equal to about 1.5 minutes, greater than or equal to about 2 minutes, greater than or equal to about 2.5 minutes, greater than or equal to about 3 minutes, greater than or equal to about 3.5 minutes, greater than or equal to about 4 minutes, greater than or equal to about 4.5 minutes, greater than or equal to about 5 minutes, greater than or equal to about 7.5 minutes, or about 10 minutes; from about 20 seconds to about 10 minutes, about 30 seconds to about 10 minutes, about 30 seconds to about 5 minutes, about 2 minutes to about 4 minutes. Examples of a suitable purge gas include, but are not limited to, Ar, N₂, He, CO, and combinations thereof.

In any embodiment, the purge gas can be delivered at a flow rate of greater than or equal to about 60 sccm, greater than or equal to about 80 sccm, greater than or equal to about 100 sccm, greater than or equal to about 120 sccm, greater than or equal to about 140 sccm, greater than or equal to about 160 sccm, greater than or equal to about 180 sccm, or about 200 sccm; or from about 60 sccm to about 200 sccm, about 80 sccm to about 200 sccm, about 100 sccm to about 200 sccm, or about 120 sccm to about 160 sccm.

In any embodiment, during the pulsing of the zerovalent Ru precursor and the carrier gas, during the delivering of the purge gas, or both, a temperature of the substrate (also referred to as deposition temperature) can be less than or equal to a thermal decomposition temperature of the zerovalent Ru precursor. For example, the temperature of the substrate can be less than or equal to about 275° C., less than or equal to about 250° C., less than or equal to about 230° C., less than or equal to about 200° C., less than or equal to about 175° C., less than or equal to about 150° C., or about 130° C.; from about 130° C. to about 275° C., about 150° C. to about 250° C., or about 200° C. to about 230° C. Decomposition temperature of a zerovalent Ru precursor can be determined by methods known to a person of ordinary skill in the art. For example, such methods can include pulsing the zerovalent Ru precursor in the absence of a co-reactant under suitable conditions, such as, a range of substrate temperatures and range of pulses and with a typical ALD purge time, e.g., 10 seconds, where observed film growth is not a self-limiting process primarily due to rapid thermal decomposition or pyrolysis of the precursor. Example 1 provided below describes how the thermal decomposition temperature of (DMBD)Ru(CO)₃ can be determined.

Additionally or alternatively, a temperature of the reactor may also be adjusted during the methods described herein, but is preferably kept below the lowest deposition temperature of a precursor as described herein, for example, 130° C. For example, a temperature of one or more of a reactor chamber wall, shower head, and precursor delivery line can be greater than or equal to about 20° C., greater than or equal to about 40° C., greater than or equal to about 60° C., greater than or equal to about 80° C., greater than or equal to about 100° C., or greater than or equal to about 120° C.; or from about 40° C. to about 120° C., or about 60° C. to about 100° C.

In various aspects, the substrate surface can comprise a metal, a dielectric material, a metal oxide material, or a combination thereof. The dielectric material can be a low-κ dielectric or a high-κ dielectric. Examples of suitable dielectric materials include, but are not limited to, SiO₂, SiON, Si₃N₄, and a combination thereof. Examples of suitable metal oxide materials include, but are not limited to, HfO₂, ZrO₂, SiO₂, Al₂O₃, TiO₂, and combinations thereof. Other suitable substrate materials include, but are not limited to crystalline silicon, Si(100), Si(111), glass, strained silicon, silicon on insulator (SOI), doped silicon or silicon oxide(s) (e.g., carbon doped silicon oxides), germanium, gallium arsenide, tantalum, tantalum nitride (TaN), aluminum, copper, ruthenium, titanium, titanium nitride (TiN), tungsten, tungsten nitride (W₂N, WN, WN₂), tungsten carbonitride (WCN), and any number of other substrates commonly encountered in nanoscale device fabrication processes (e.g., semiconductor fabrication processes). In some embodiments, the substrate can comprise one or more of silicon oxide, aluminum oxide, titanium nitride, tungsten nitride, tungsten carbon nitride, and tantalum nitride. As will be appreciated by those of skill in the art, substrates may be exposed to a pretreatment process to polish, etch, reduce, oxidize, hydroxylate, anneal and/or bake the substrate surface. In one or more embodiments, the substrate surface contains a hydrogen-terminated surface.

The properties of a specific zerovalent Ru precursor for use in the methods disclosed herein can be evaluated using methods known in the art, allowing selection of appropriate temperature and pressure for the reaction. In general, lower molecular weight and the presence of functional groups that increase the rotational entropy of the ligand sphere result in a melting point that yields liquids at typical delivery temperatures and increased vapor pressure.

A zerovalent Ru precursor for use in the methods will have all of the requirements for sufficient vapor pressure, sufficient thermal stability at the selected substrate temperature and sufficient reactivity to produce a reaction on the surface of the substrate without unwanted impurities in the thin film. Sufficient vapor pressure ensures that molecules of the source compound are present at the substrate surface in sufficient concentration to enable a complete self-saturating reaction. Sufficient thermal stability ensures that the source compound will not be subject to the thermal decomposition which produces impurities in the thin film.

Examples of pulsed CVD growth conditions for the zerovalent Ru precursor disclosed herein include, but are not limited to:
(1) Substrate temperature: 130 - 275° C.
(2) Evaporator temperature (metal precursor temperature): 20 - 70° C.
(3) Reactor pressure: 0.01 - 10 Torr
(4) Argon or nitrogen carrier gas flow rate: 60 - 200 sccm
(5) Number of cycles: will vary according to desired film thickness.

In further embodiments, the methods described herein may be performed under conditions to provide conformal growth for the ruthenium-containing film. As used herein, the term “conformal growth” refers to a deposition process wherein a film is deposited with substantially the same thickness along one or more of a bottom surface, a sidewall, an upper corner, and outside a feature. “Conformal growth” is also intended to encompass some variations in film thickness, e.g., the film may be thicker outside a feature and/or near a top or upper portion of the feature compared to the bottom or lower portion of the feature.

Conformal conditions include, but are not limited to temperature (e.g., of substrate, zerovalent Ru precursor, carrier gas, purge gas), pressure (e.g., during delivery of zerovalent Ru precursor, carrier gas, purge gas), amount of zerovalent Ru precursor delivered, length of purge time and/or amount of purge gas delivered. In various aspects, the substrate may comprise one or more features where conformal growth may occur.

In various aspects, the feature may be a via, a trench, contact, dual damascene, etc. A feature may have a non-uniform width, also known as a “re-entrant feature,” or a feature may have substantially uniform width.

In one or more embodiments, a ruthenium-containing film grown following the methods described herein may have substantially no voids and/or hollow seams.

In any embodiments, the methods described herein can further comprise annealing the Ru-containing films at higher temperatures. In other words, annealing can be performed after the last deposition cycle for forming the Ru-containing film.

Therefore, in some embodiments, the Ru-containing film may be annealed under vacuum, or in the presence of an inert gas such as Ar or N₂, or a reducing agent such as H₂, or a combination thereof, such as, for example, 5% H₂ in Ar. Without being bound by theory, the annealing step may remove incorporated impurities, such as, for example, carbon, oxygen and/or nitrogen, to reduce the resistivity and to further improve film quality by densification at elevated temperatures. Annealing may be performed at a temperature of greater than or equal to about 200° C., greater than or equal to about 300° C., greater than or equal to about 400° C., greater than or equal to about 500° C., or about 800° C.; from about 200° C. to about 800° C. or about 300° C. to about 500° C.

The Ru-containing films formed from the methods described herein can have a lower resistivity. In some embodiments, a Ru-containing film may have resistivity of greater than or equal to about 20 µΩ-cm, greater than or equal to about 30 µΩ-cm, greater than or equal to about 60 µΩ-cm, greater than or equal to about 80 µΩ-cm, greater than or equal to about 100 µΩ-cm, greater than or equal to about 150 µΩ-cm, greater than or equal to about 180 µΩ-cm, greater than or equal to about 200 µΩ-cm, or about 250 µΩ-cm; or from about 20 µΩ-cm to about 250 µΩ-cm, about 30 µΩ-cm to about 200 µΩ-cm, about 30 µΩ-cm to about 180 µΩ-cm, or about 30 µΩ-cm to about 150 µΩ-cm. In some embodiments, the resistivity of the Ru-containing film can be lowered following annealing of the Ru-containing film, for example, to a resistivity of greater than or equal to about 10 µΩ-cm, greater than or equal to about 20 µΩ-cm, greater than or equal to about 40 µΩ-cm, greater than or equal to about 60 µΩ-cm, greater than or equal to about 80 µΩ-cm, greater than or equal to about 100 µΩ-cm, or about 175 µΩ-cm; or from about 10 µΩ-cm to about 175 µΩ-cm, about 20 µΩ-cm to about 80 µΩ-cm, or about 20 µΩ-cm to about 60 µΩ-cm.

The resistance measurements noted above may be achieved in Ru-containing films prepared by the methods described herein having a thickness of about 1 nm to about 20 nm, about 1 nm to about 15 nm, about 2 nm to about 15 nm, about 2 nm to about 10 nm, or about 1 nm to about 5 nm measured by X-ray fluorescence (XRF).

Additionally or alternatively, the Ru-containing films formed according to the methods described herein can have a growth rate of greater than or equal to about 0.1 Å/cycle, greater than or equal to about 0.5 Å/cycle, greater than or equal to about 1 Å/cycle, greater than or equal to about 1.5 Å/cycle, greater than or equal to about 2 Å/cycle, greater than or equal to about 2.5 Å/cycle, or about 5 Å/cycle; or from about 0.1 Å/cycle to about 5 Å/cycle, about 0.1 Å/cycle to about 2.5 Å/cycle, or about 0.1 Å/cycle to about 2 Å/cycle.

### Applications

The films formed from the processes described herein are useful for memory and/or logic applications, such as dynamic random access memory (DRAM), complementary metal oxide semi-conductor (CMOS) and 3D NAND, 3D Cross Point and ReRAM.

Reference throughout this specification to “one embodiment,” “certain embodiments,” “one or more embodiments” or “an embodiment” means that a particular feature, structure, material, or characteristic described in connection with the embodiment is included in at least one embodiment of the present technology. Thus, the appearances of the phrases such as “in one or more embodiments,” “in certain embodiments,” “in one embodiment” or “in an embodiment” in various places throughout this specification are not necessarily referring to the same embodiment of the present technology. Furthermore, the particular features, structures, materials, or characteristics may be combined in any suitable manner in one or more embodiments.

Although the present technology herein has been described with reference to particular embodiments, it is to be understood that these embodiments are merely illustrative of the principles and applications of the present technology. It will be apparent to those skilled in the art that various modifications and variations can be made to the method and apparatus of the present technology without departing from the spirit and scope of the present technology. Thus, it is intended that the present technology include modifications and variations that are within the scope of the appended claims and their equivalents. The present technology, thus generally described, will be understood more readily by reference to the following examples, which is provided by way of illustration and is not intended to be limiting.

### EXAMPLES

(DMBD)Ru(CO)₃ (also referred to as RuDMBD) was utilized as the precursor in the following examples. Methods of preparing (DMBD)Ru(CO)₃ are known in the art. For example, see U.S. 2011/0165780, which is incorporated herein by reference in its entirety.

Unless otherwise indicated, a Ru film was deposited using (DMBD)Ru(CO)₃ in a pulsed CVD process in a CN1 ALD/CVD reactor with the following conditions and materials:
i. Carrier and purge gas: argon from ultra-high purity liquid argon, further purified using a SAES Pure Gas/Entegris inert gas purifier at point of use to remove H₂O, O₂, CO, CO₂ and H₂ to <100 ppt by volume, and acids and organics, etc. to < 1 ppt by volume;
ii. Carrier and purge gas flow rates: 145 sccm unless noted otherwise;
iii. Deposition pressure: 1.4 Torr;
iv. RuDMBD at 26° C.-28° C., pulse time 5 sec, bubbler carrier gas flow of 25 sccm Ar;
v. Purge time: 2 to 4 minutes each;
vi. Substrates:
   a. SiO₂: 100 nm thick thermal oxide on Si;
   b. Al₂O₃: ~4 nm thick Al₂O₃ on 100 nm thick SiO₂;
   c. WCN: ~4 nm thick WCN on 100 nm thick SiO₂;
vii. Annealing: 400° C. in Ar at 1.5-1.7 Torr for 30 minutes;
viii. X-ray fluorescence (XRF) thickness vs. ellipsometer thickness of Ru:
   a. XRF thickness only reveals the amount of Ru in film and was used for thickness and growth rate comparisons when necessary;
   b. Ellipsometer thickness includes Ru and impurities and is close to true film thickness measured by scanning electron microscopy (SEM). Resistivities calculated were measured using ellipsometer thicknesses.

### Example 1 -Thermal Stability of RuDMBD Precursor

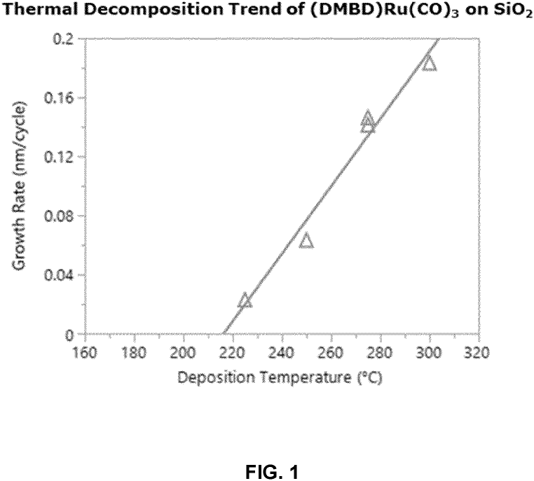

Growth rate of a Ru film on a 100 nm thick SiO₂ substrate was determined by pulsing RuDMBD heated to 40° C. in Ar at 1 Torr with a pulse time of 1 sec and purge time of 10 sec. each without a co-reactant. The following pulses were delivered at various temperatures: 50 pulses at 300° C.; 85 pulses at 275° C.; 115 pulses at 250° C., and 450 pulses at 225° C. The average growth rate of the Ru film formed on the SiO₂ substrate at the aforementioned temperatures is shown in FIG. 1.

Thermal decomposition of RuDMBD started at ~225° C. above which the growth rate increased rapidly. There appeared to be little or no deposition at lower temperatures below ~225° C. with a short purge time of 10 sec. per pulse.

### Example 2 -Ru Deposition With and Without H₂O Co-Reactant

Ru-containing films on three substrates, SiO₂, WCN, and Al₂O₃, were prepared via a pulsed CVD method described above using H₂O as a co-reactant and without the use of an H₂O co-reactant. The deposition cycle sequence was as follows: RuDMBD pulse/purge time/H₂O pulse/purge time: 5 sec./120 sec./ n /120 sec. The substrate temperature was 215° C. and the deposition pressure was 1.4 Torr. The H₂O pulse had a variable pulse time “n” from zero (no H₂O) to 0.65 sec. The number of deposition cycles was 100. The thickness of the Ru films formed on the SiO₂ and WCN substrates ranged from 12.3 nm to 13.7 nm. The thickness of the Ru films formed on the Al₂O₃ substrate ranged from 8.2 nm to 11.7 nm. Ru film thickness was determined by XRF.

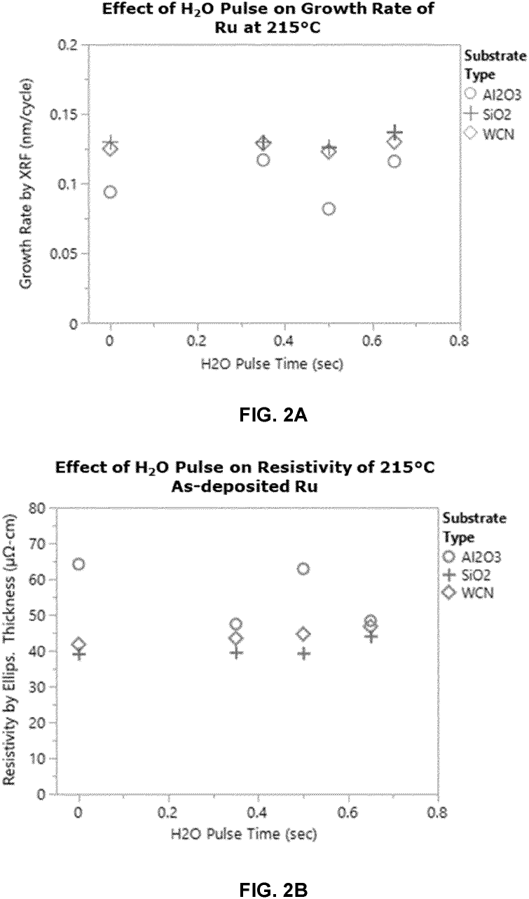

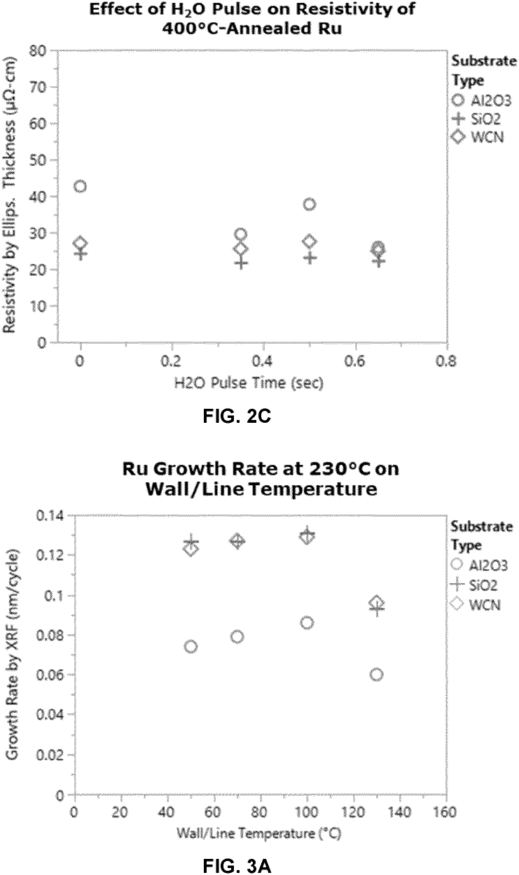

Growth rate and resistivity of the as-deposited Ru films (“as-deposited Ru”) were measured. FIG. 2A shows the effect of H₂O pulse time on growth rate. FIG. 2B shows the effect of H₂O pulse time on resistivity of the as-deposited Ru films. The Ru films underwent further annealing as described above, and FIG. 2C shows the effect of H₂O pulse time on resistivity of the annealed Ru films (“400° C.-annealed Ru” films).

As shown in FIGS. 2A-2C, a low resistivity Ru film was deposited with high growth rate without H₂O or any co-reactant on various substrates below the thermal decomposition temperature of RuDMBD by extended purging, i.e., 240 sec when “n” is zero. The H₂O pulse had no significant effect on growth rate and resistivity

### Example 3—Effect of Reactor Chamber Conditions on Ru Film Growth Rate and Resistivity

Ru-containing films on three substrates, SiO₂, WCN, and Al₂O₃, were prepared via a pulsed CVD method described above without the use of a co-reactant at various temperatures of the reactor chamber wall, shower head and precursor delivery line. The deposition cycle sequence was as follows: RuDMBD pulse/purge time: 5 sec./180 sec. The substrate temperature was 230° C. and the deposition pressure was 1.4 Torr. The number of pulses was 70.

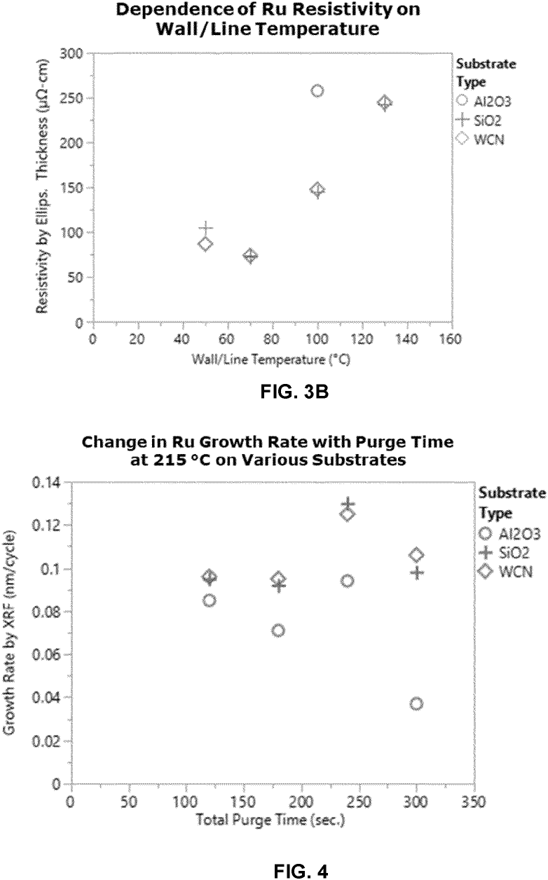

Growth rate and resistivity of the formed Ru films were measured. FIG. 3A shows the effect of chamber wall, shower head and line temperature on growth rate. FIG. 3B shows the effect of chamber wall, shower head and line temperature on resistivity of the Ru films (as-deposited Ru).

There appeared to be no significant effect of the chamber wall, shower head and precursor delivery line temperatures of 100° C. or lower on growth rate, but growth rate dropped at the chamber wall, shower head, and precursor delivery line temperatures of 130° C. most likely due to reduced precursor flux on substrates as a result of secondary deposition in the precursor delivery line and shower head.

There was a significant effect on resistivity of the Ru films depending on the chamber wall, shower head, and precursor delivery line temperatures. There were lower resistivity Ru films formed with decreasing chamber wall, shower head, and precursor delivery line temperatures, which was likely due to reduced outgassing of absorbed precursor from delivery path and chamber walls.

### Example 4—Effect of Purge Gas Flow Rate on Ru Film Growth Rate and Resistivity

Ru-containing films on three substrates, SiO₂, WCN, and Al₂O₃, were prepared via a pulsed CVD method described above without the use of a co-reactant at various purge gas flow rates. The deposition cycle sequence was as follows: RuDMBD pulse/purge time: 5 sec./180 sec. The substrate temperature was 230° C. and the deposition pressure was 1.4 Torr. The number of pulses was 70. The chamber wall, shower head, and precursor delivery line temperatures were 70° C.

Growth rate (thickness) and resistivity of the formed Ru films were measured and the results are shown below in Table 1.

TABLE 1

| Substrate | Total Ar Flow (sccm) | XRF Ru Thickness (nm) | Ellips. Thickness (nm) | Resistivity by Ellips. Thickness (µΩ-cm) |
|---|---|---|---|---|
| Al₂O₃ | 85 | 4.3 | 9.3 | 3227 |
| Al₂O₃ | 145 | 7.2 | 13.6 | 278 |
| SiO₂ | 85 | 9.2 | 15.3 | 213 |
| SiO₂ | 145 | 8.0 | 13.3 | 136 |
| WCN | 85 | 8.9 | 16.2 | 217 |
| WCN | 145 | 8.0 | 13.0 | 109 |

The purge gas flow rate had no significant effect on growth rate (thickness) except on Al₂O₃ The purge gas flow rate did have an effect on resistivity of the Ru films formed. It is believed that resistivity decreased with increasing Ar gas flow rates due to increased purging that can facilitate removal of ligand byproducts from the film surface.

### Example 5—Effect of Duration of Purge Gas Delivery on Ru Film Growth Rate

Ru-containing films on three substrates, SiO₂, WCN, and Al₂O₃, were prepared via a pulsed CVD method described above without the use of a co-reactant at various purge gas delivery times. The deposition cycle sequence was as follows: RuDMBD pulse/purge time: 5 sec./120 sec to 300 sec. The substrate temperature was 215° C. and the deposition pressure was 1.4 Torr. The number of pulses was 95-110. The thickness of the Ru films formed on the SiO₂ and WCN substrates ranged from 9 nm to 13 nm. The thickness of the Ru films formed on the Al₂O₃ substrate ranged from 3.5 nm to 9.4 nm. Ru film thickness was determined by XRF.

Growth rate of the formed Ru films was measured and the results are shown in FIG. 4. Growth rate did not change significantly with purge time in the range tested except on Al₂O₃, where the rapid drop in growth rate with increasing purge time was likely due to slower dissociation of RuDMBD on Al₂O₃ surface and thus a longer nucleation delay which led to increased desorption of precursor with a longer purge time.

### Example 6—Effect of Duration of Purge Gas Delivery on Ru Film Resistivity

Ru-containing films on three substrates, SiO₂, WCN, and Al₂O₃, were prepared via a pulsed CVD method described above without the use of a co-reactant at various purge gas delivery times. The deposition cycle sequence was as follows: RuDMBD pulse/purge time: 5 sec./120 sec to 300 sec. The substrate temperature was 215° C. and the deposition pressure was 1.4 Torr. The number of pulses was 95-110. The thickness of the Ru films formed on the SiO₂ and WCN substrates ranged from 9 nm to 13 nm. The thickness of the Ru films formed on the Al₂O₃ substrate ranged from 3.5 nm to 9.4 nm. Ru film thickness was determined by XRF.

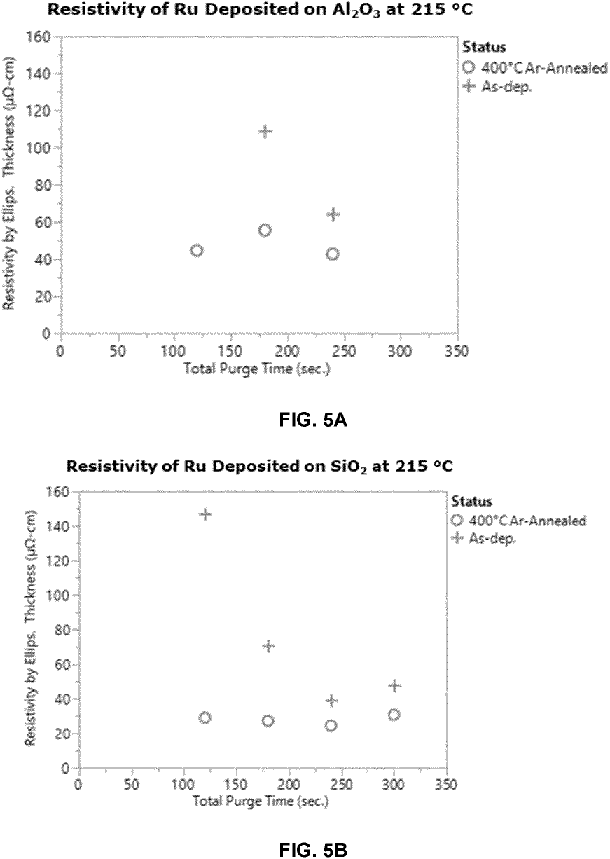

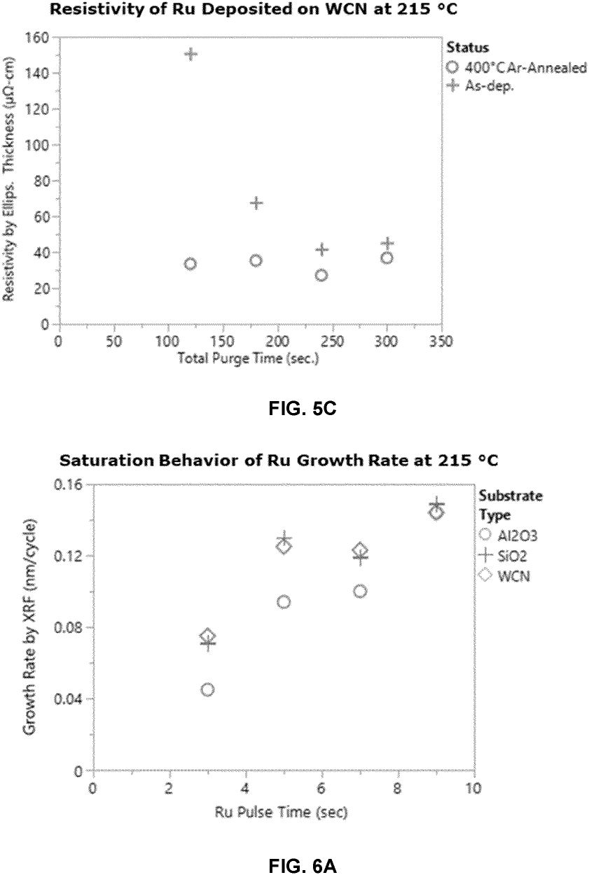

Resistivity of the as-deposited Ru films (“as-dep” films) was measured. The Ru films underwent further annealing as described above and resistivity of the annealed films was measured (“400° C. Ar-annealed” films). FIG. 5A shows the effect of purge time on resistivity for the films grown on an Al₂O₃ substrate. FIG. 5B shows the effect of purge time on resistivity for the films grown on a SiO₂ substrate. FIG. 5C shows the effect of purge time on resistivity for the films grown on a WCN substrate. Resistivity of as-deposited film decreased rapidly with increasing purge time on all three different substrates. Resistivity of annealed films was similarly low, for example, ~20 µΩ-cm.

### Example 7—Effect of Pulse Time of RuDMBD on Saturation Behavior

Ru-containing films on three substrates, SiO₂, WCN, and Al₂O₃, were prepared via a pulsed CVD method described above without the use of a co-reactant at various pulse times of RuDMBD. The deposition cycle sequence was as follows: RuDMBD pulse/purge time: 3 sec. to 9 sec./240 sec. The substrate temperature was 215° C. The number of pulses was 100.

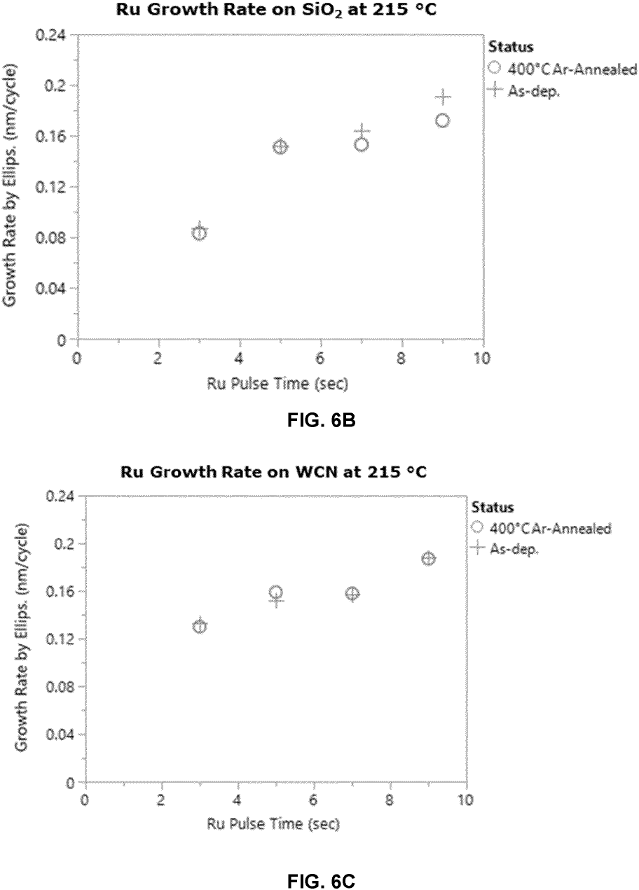

Growth rate of the as-deposited Ru films (“as-dep” films) was measured. The Ru films formed on the SiO₂ and WCN substrates underwent further annealing as described above and growth rate of the annealed films was measured (“400° C. Ar-annealed” films). FIG. 6A shows the effect of pulse time of RuDMBD on growth rate for the films grown on an all three substrates. FIG. 6B shows the effect of pulse time of RuDMBD on growth rate for the as deposited and annealed films grown on a SiO₂ substrate. FIG. 6C shows the effect of pulse time of RuDMBD on growth rate for the as deposited and annealed films grown on a WCN substrate. Partially self-limiting growth behavior below the thermal decomposition temperature of the precursor was observed. The growth rate did not fully saturate like ALD but was also not linear like a pure CVD process.

### Example 8—Effect of Deposition Temperature on Ru Film Growth Rate

Ru-containing films on three substrates, SiO₂, WCN, and Al₂O₃, were prepared via a pulsed CVD method described above without the use of a co-reactant at various substrate temperatures. The deposition cycle sequence was as follows: RuDMBD pulse/purge time: 5 sec./240 sec. The deposition pressure was 1.4 Torr. The number of pulses at various substrate temperature was as follows: 120 pulses at 185° C.; 100 pulses at 200-230° C.; 65 pulses at 250° C.; and 30 pulses at 300° C.

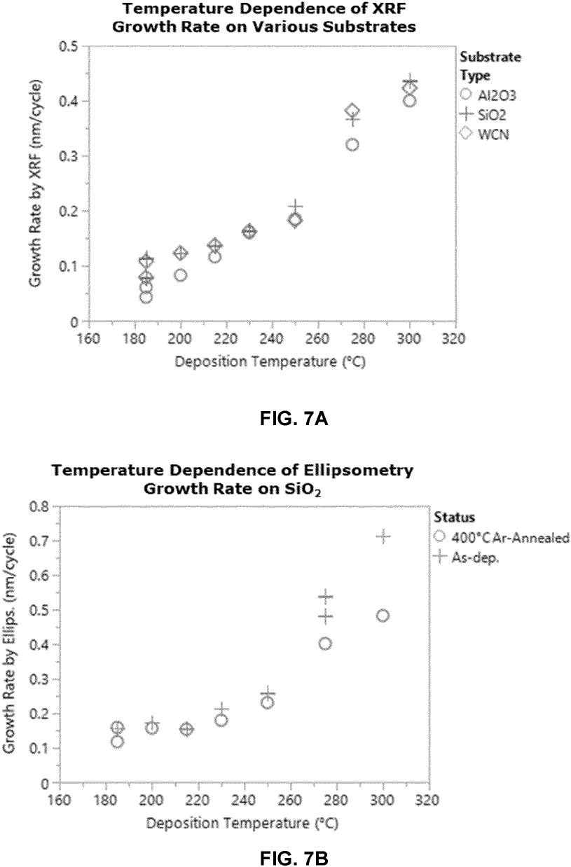

Growth rate of the as-deposited Ru films (“as-dep” films) was measured. The Ru films formed on the SiO₂ substrate underwent further annealing as described above and growth rate of the annealed films was measured (“400° C. Ar-annealed” films). FIG. 7A shows the effect of substrate temperature on growth rate (determined by XRF) for the films grown on an all three substrates. FIG. 7B shows the effect of substrate temperature on growth rate (as determined by ellipsometry) for the as deposited and annealed films grown on a SiO₂ substrate. The growth rate below ~230° C. was not strongly temperature dependent on SiO₂ and WCN substrate. The observed rapid increase in growth rate at ~250° C. or higher was due to thermal decomposition.

### Example 9- Effect of Deposition Temperature on Ru Film Resistivity

Ru-containing films on three substrates, SiO₂, WCN, and Al₂O₃, were prepared via a pulsed CVD method described above in Example 8.

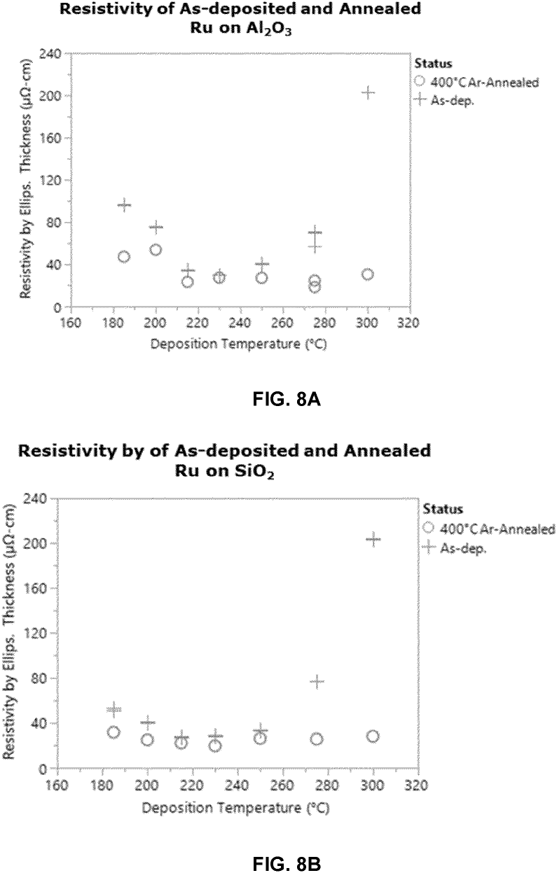

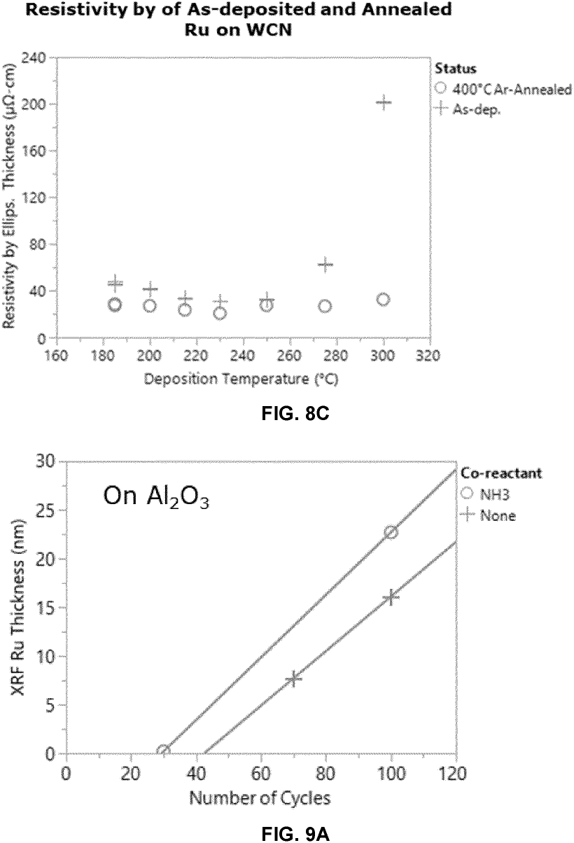

Resistivity of the as-deposited Ru films (“as-dep” films) was measured. The Ru films underwent further annealing as described above and resistivity of the annealed films was measured (“400° C. Ar-annealed” films). FIG. 8A shows the effect of substrate temperature on resistivity for the films grown on an Al₂O₃ substrate. FIG. 8B shows the effect of substrate temperature on resistivity for the films grown on a SiO₂ substrate. FIG. 8C shows the effect of substrate temperature on resistivity for the films grown on a WCN substrate. The optimal deposition temperature was observed at 215-230° C., which is near or below the thermal decomposition temperature of the RuDMBD precursor. The annealed films exhibited the lowest resistivity. At deposition temperatures above 230° C., some films became inhomogeneous after annealing and high resistivity regions appeared.

### Example 10—Ru Deposition With and Without NH₃ Co-Reactant Effect on Ru Film Growth Rate

Ru-containing films on three substrates, SiO₂, WCN, and Al₂O₃, were prepared via a pulsed CVD method described above with the use of NH₃ as a co-reactant and without the use of a co-reactant. The deposition cycle sequence without NH₃ co-reactant was as follows: RuDMBD pulse/purge time: 5 sec./240 sec. The deposition cycle sequence with NH₃ co-reactant was as follows: RuDMBD pulse/purge time/NH₃ pulse/purge time: 5 sec./120 sec./5 sec./115 sec. The substrate temperature was 230° C. and deposition pressure was 1.4 Torr. The number of deposition cycles varied from 25 cycles to 100 cycles.

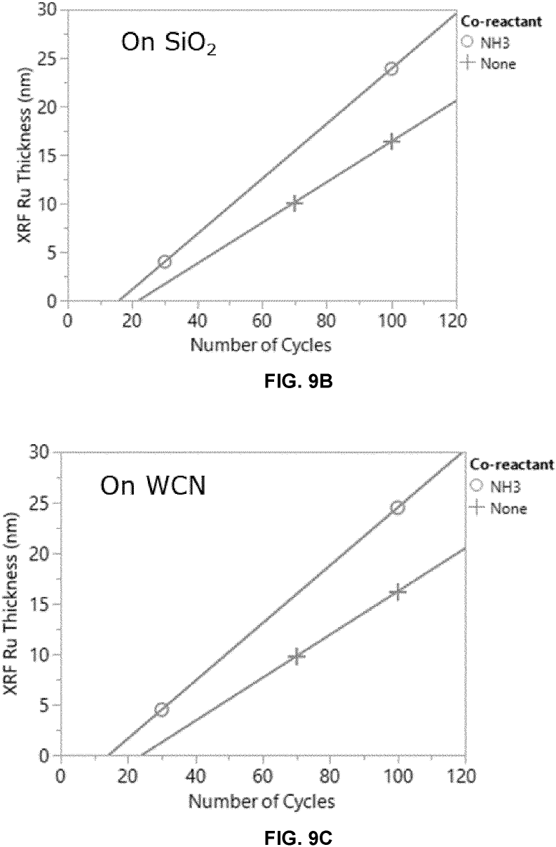

Ru film thickness (as determined by XRF) of the formed Ru films was measured. FIG. 9A shows the effect of number of cycles on Ru film thickness for films grown on an Al₂O₃ substrate. FIG. 9B shows the effect of number of cycles on Ru film thickness for the films grown on a SiO₂ substrate. FIG. 9C shows the effect of number of cycles on Ru film thickness for the films grown on a WCN substrate. NH₃ had very little effect on growth rate with a short purge time, such as 10 sec for RuDMBD, but can increase growth rate significantly with a longer purge time, such as 60-120 sec, due to its reactivity with Ru; thus, resulting in a shorter nucleation delay and a slight increase in the liner slope on all 3 different substrates.

### Example 11-Ru Deposition With and Without NH₃ Co-Reactant Effect on Ru Film Resistivity

Ru-containing films on two substrates, SiO₂ and WCN, were prepared via a pulsed CVD method described above with the use of NH₃ as a co-reactant and without the use of a co-reactant. The deposition cycle sequence without NH₃ co-reactant was as follows: RuDMBD pulse/purge time: 5 sec./120 sec. The deposition cycle sequence with NH₃ co-reactant was as follows: RuDMBD pulse/purge time/NH₃ pulse/purge time: 5 sec./60 sec./5 sec./55 sec. The substrate temperature was 230° C. and deposition pressure was 1.4 Torr.

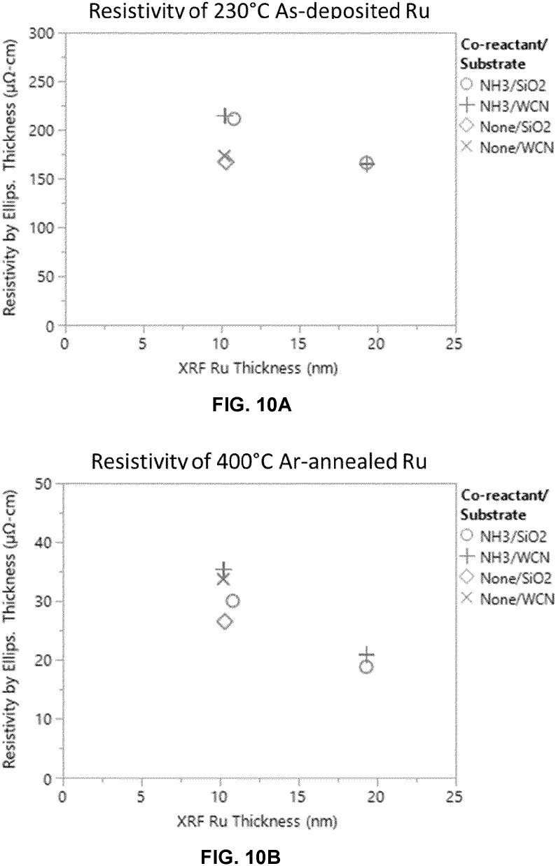

Resistivity of the as-deposited Ru films (“as-deposited Ru” films) was measured. The Ru films underwent further annealing as described above and resistivity of the annealed films was measured (“400° C. Ar-annealed” films). FIG. 10A shows the effect of Ru film thickness (as measured by XRF) on resistivity for the as-deposited films on SiO₂ and WCN. FIG. 10B shows the effect of Ru film thickness (as measured by XRF) on resistivity for the 400° C. Ar-annealed films on SiO₂ and WCN. NH₃ could not react with RuDMBD with a short purge time such as 10 sec and no N was found by X-ray photoelectron spectroscopy (XPS). About 6 at% N was found in as-deposited film on SiO₂ formed using the NH₃ co-reactant with a longer purge time of 60 sec. N incorporation caused an increase in resistivity as compared with the co-reactant-free Ru film of the same thickness of 10 nm. After 400° C. Ar-annealing, N was removed completely and became undetectable by XPS, and thus film resistivity reached the same level as that of annealed co-reactant-free Ru.

All publications, patent applications, issued patents and other documents referred to in this specification are herein incorporated by reference as if each individual publication, patent application, issued patent, or other document was specifically and individually indicated to be incorporated by reference in its entirety. Definitions that are contained in text incorporated by reference are excluded to the extent that they contradict definitions in this disclosure.

The words “comprise”, “comprises”, and “comprising” are to be interpreted inclusively rather than exclusively.

1. A pulsed chemical vapor deposition (CVD) method for depositing a ruthenium-containing film, the pulsed CVD method comprising at least one deposition cycle,
wherein the deposition cycle comprises:
a. pulsing a zerovalent Ru precursor with a carrier gas in the absence of a coreactant onto a surface of a substrate; and
b. delivering a purge gas to the surface of the substrate.

2. The method of claim 1, wherein the zerovalent Ru precursor corresponds in structure to Formula I: 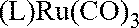
wherein: L is selected from the group consisting of a linear or branched C₂-C₆-alkenyl, a linear or branched C₁-C₆-alkyl, a C₃-C₆ cycloalkenyl, and a linear, branched, or cyclic dienyl-containing moiety; and wherein L is optionally substituted with one or more substituents independently selected from the group consisting of C₂-C₆-alkenyl, C₁-C₆-alkyl, alkoxy and NR¹R²; wherein R¹ and R² are independently alkyl or hydrogen; or
wherein the zerovalent Ru precursor is (ethylbenzyl)(1-ethyl-1,4-cyclohexadienyl)ruthenium.

3. The method of claim 2, wherein L is a linear, branched, or cyclic dienyl-containing moiety.

4. The method of claim 2, wherein L is a linear, branched, or cyclic dienyl-containing moiety selected from the group consisting of butadienyl, pentadienyl, hexadienyl, cyclohexadienyl, heptadienyl and octadienyl.

5. The method of claim 2, wherein the zerovalent Ru precursor is selected from the group consisting of:
(η⁴-buta-1,3-diene)tricarbonylruthenium;
(η⁴-2,3-dimethylbuta-1,3-diene)tricarbonylruthenium;
(η⁴-2-methylbuta-1,3-diene)tricarbonylruthenium; and
(cyclohexadiene)tricarbonylruthenium.

6. The method of claim 1, wherein the pulsing the zerovalent Ru precursor is for greater than or equal to about 1 second.

7. The method of claim 1, wherein the pulsing the zerovalent Ru precursor is for about 1 second to about 10 seconds.

8. The method of claim 1, wherein the pulsing the zerovalent Ru precursor is performed at a pressure of about 0.1 Torr to about 5 Torr.

9. The method of claim 1, wherein the delivering the purge gas is for at least about 30 seconds.

10. The method of claim 1, wherein the delivering the purge gas is for about 30 seconds to about 5 minutes.

11. (canceled)

12. The method of claim 1, wherein during the pulsing of the zerovalent Ru precursor and the carrier gas and/or during the delivering of the purge gas, a temperature of the substrate is less than or equal to a thermal decomposition temperature of the zerovalent Ru precursor.

13. The method of claim 12, wherein the temperature of the substrate is about 150° C. to about 250° C.

14. (canceled)

15. The method of claim 1, wherein the substrate comprises one or more of SiO₂, Al₂O₃, TiN, WN, and WCN.

16. The method of claim 1, wherein the zerovalent Ru precursor is preheated to a temperature of about 20° C. to about 50° C. before pulsing.

17. The method of claim 1, wherein the carrier gas and the purge gas are each independently selected from the group consisting of Ar, N₂, He, CO, and a combination thereof.

18. The method of claim 1, wherein the carrier gas is preheated to a temperature of about 20° C. to about 100° C. before pulsing.

19. The method of claim 1, wherein the ruthenium-containing film has a resistivity of about 30 µΩ-cm to about 180 µΩ-cm.

20. The method of claim 1, wherein the ruthenium-containing film has a growth rate of about 0.1 Å/cycle to about 2 Å/cycle.

21. The method of claim 1, further comprising annealing the ruthenium-containing film at a temperature of about 300° C. to about 500° C.

22. The method of claim 21, wherein the annealed ruthenium-containing film has a resistivity of about 20 µΩ-cm to about 60 µΩ-cm.
